(19) United States
(12) Patent Application Publication
(10) Pub. No.: US 2025/0317121 A1
(43) Pub. Date: Oct. 9, 2025

(54) MULTI-LAYER PIEZOELECTRIC SUBSTRATE SURFACE ACOUSTIC WAVE DEVICE WITH LOOP CIRCUIT

(71) Applicant: Skyworks Solutions, Inc., Irvine, CA (US)

(72) Inventors: Motoyuki Tajima, Yokohama-Shi (JP); Noriaki Taniguchi, Sagamihara-Shi (JP); Rei Goto, Osaka-Shi (JP)

(21) Appl. No.: 19/091,390

(22) Filed: Mar. 26, 2025

Related U.S. Application Data
(60) Provisional application No. 63/631,133, filed on Apr. 8, 2024.
(60) Provisional application No. 63/631,103, filed on Apr. 8, 2024.
(60) Provisional application No. 63/631,117, filed on Apr. 8, 2024.
(60) Provisional application No. 63/631,140, filed on Apr. 8, 2024.

(51) Int. Cl. H03H 9/64; H03H 3/08; H03H 9/02

(52) U.S. Cl. CPC H03H 9/6443; H03H 3/08; H03H 9/02574; H03H 9/6489

(57) ABSTRACT

A multi-layer piezoelectric substrate surface acoustic wave device is disclosed. The acoustic wave device can include a multi-layer piezoelectric substrate including a support substrate and a piezoelectric layer, a filter circuit including a plurality of resonators in electrical communication with the piezoelectric layer and a phase cancelling circuit integrated with the filter circuit. The piezoelectric layer has a first side facing the support substrate, a second side opposite the first side, and a sidewall extending between the first side and the second side and defining a periphery of the piezoelectric layer. The sidewall is tapered such that the first side is wider than the second side. An acoustic track of the phase cancelling circuit is offset from the plurality of resonators.

### INCORPORATION BY REFERENCE TO ANY PRIORITY APPLICATIONS

Any and all applications for which a foreign or domestic priority claim is identified in the Application Data Sheet as filed with the present application, including U.S. Provisional Patent Application No. 63/631,133, filed Apr. 8, 2024, titled “MULTI-LAYER PIEZOELECTRIC SUBSTRATE SURFACE ACOUSTIC WAVE DEVICE WITH PHASE CANCELLING CIRCUIT,” U.S. Provisional Patent Application No. 63/631,103, filed Apr. 8, 2024, titled “MULTI-LAYER PIEZOELECTRIC SUBSTRATE SURFACE ACOUSTIC WAVE DEVICE WITH LOOP CIRCUIT,” U.S. Provisional Patent Application No. 63/631,117, filed Apr. 8, 2024, titled “INTERFERENCE SUPPRESSION STRUCTURE FOR PHASE CANCELLING CIRCUIT IN MULTI-LAYER PIEZOELECTRIC SUBSTRATE SURFACE ACOUSTIC WAVE DEVICE,” and U.S. Provisional Patent Application No. 63/631,140, filed Apr. 8, 2024, titled “PHASE CANCELLING CIRCUIT IN MULTI-LAYER PIEZOELECTRIC SUBSTRATE SURFACE ACOUSTIC WAVE DEVICE WITH INTERFERENCE SUPPRESSION STRUCTURE,” are hereby incorporated by reference under 37 CFR 1.57 in their entirety.

### BACKGROUND

### Field

Embodiments of this disclosure relate to multi-layer piezoelectric substrate surface acoustic wave (MPS-SAW) devices.

### Description of Related Technology

Acoustic wave filters can be implemented in radio frequency electronic systems. For instance, filters in a radio frequency front end of a mobile phone can include acoustic wave filters. An acoustic wave filter can filter a radio frequency signal. An acoustic wave filter can be a band pass filter. A plurality of acoustic wave filters can be arranged as a multiplexer. For example, two acoustic wave filters can be arranged as a duplexer.

An acoustic wave filter can include a plurality of resonators arranged to filter a radio frequency signal. Example acoustic wave filters include surface acoustic wave (SAW) filters and bulk acoustic wave (BAW) filters. A surface acoustic wave resonator can include an interdigital transductor electrode on a piezoelectric substrate. The surface acoustic wave resonator can generate a surface acoustic wave on a surface of the piezoelectric layer on which the interdigital transductor electrode is disposed.

### SUMMARY

The innovations described in the claims each have several aspects, no single one of which is solely responsible for its desirable attributes. Without limiting the scope of the claims, some prominent features of this disclosure will now be briefly described.

In some aspects, the techniques described herein relate to a multi-layer piezoelectric substrate surface acoustic wave device including: a multi-layer piezoelectric substrate including a support substrate and a piezoelectric layer, the piezoelectric layer having a first side facing the support substrate, a second side opposite the first side, and a sidewall extending between the first side and the second side and defining a periphery of the piezoelectric layer, the sidewall tapered such that the first side is wider than the second side; a filter circuit in electrical communication with the piezoelectric layer; and a phase cancelling circuit integrated with the filter circuit, an acoustic track of the phase cancelling circuit extending between a first periphery portion and a second periphery portion of the sidewall, the phase cancelling circuit being positioned within center seventy percent of a width between the first periphery portion and the second periphery portion.

In some embodiments, the techniques described herein relate to an acoustic wave device wherein an angle between the second side and the sidewall is in a range between 15° and 80°.

In some embodiments, the techniques described herein relate to an acoustic wave device wherein the multi-layer piezoelectric substrate further includes a silicon oxide layer between the support substrate and the piezoelectric layer.

In some embodiments, the techniques described herein relate to an acoustic wave device wherein the filter circuit includes a transmit filter connected to an antenna and a receive filter connected to the antenna, the phase cancelling circuit is electrically connected between a transmit port of the transmit filter and the antenna and between a receive port of the receive filter and the antenna.

In some embodiments, the techniques described herein relate to an acoustic wave device wherein the phase cancelling circuit includes a plurality of longitudinally coupled interdigital transducer electrodes.

In some embodiments, the techniques described herein relate to an acoustic wave device wherein the phase cancelling circuit is positioned within center fifty percent of the width.

In some embodiments, the techniques described herein relate to an acoustic wave device further including an acoustic wave obstacle in the acoustic track.

In some embodiments, the techniques described herein relate to an acoustic wave device further including a second filter circuit in electrical communication with the piezoelectric layer, and a second phase cancelling circuit integrated with the second filter circuit.

In some embodiments, the techniques described herein relate to an acoustic wave device wherein a second acoustic track of the second phase cancelling circuit extends between a third periphery portion and a fourth periphery portion of the sidewall, the second phase cancelling circuit is positioned within center seventy percent of a second width between the third periphery portion and the fourth periphery portion.

In some embodiments, the techniques described herein relate to an acoustic wave device wherein the first periphery portion is closer to the phase cancelling circuit than the second periphery portion, the phase cancelling circuit is spaced at least 200 micrometers from the first periphery portion.

In some aspects, the techniques described herein relate to a method of manufacturing a multi-layer piezoelectric substrate surface acoustic wave device, the method including: providing a multi-layer piezoelectric substrate including a support substrate and a piezoelectric layer, the piezoelectric layer having a first side facing the support substrate, a second side opposite the first side, and a sidewall extending between the first side and the second side and defining a periphery of the piezoelectric layer, the sidewall tapered such that the first side is wider than the second side; forming a filter circuit in electrical communication with the piezoelectric layer; and providing a phase cancelling circuit integrated with the filter circuit, an acoustic track of the phase cancelling circuit extending between a first periphery portion and a second periphery portion of the sidewall, the phase cancelling circuit being positioned within center seventy percent of a width between the first periphery portion and the second periphery portion.

In some embodiments, the techniques described herein relate to a method wherein an angle between the second side and the sidewall is in a range between 15° and 80°.

In some embodiments, the techniques described herein relate to a method wherein the multi-layer piezoelectric substrate further includes a silicon oxide layer between the support substrate and the piezoelectric layer.

In some embodiments, the techniques described herein relate to a method wherein the filter circuit includes a transmit filter connected to an antenna and a receive filter connected to the antenna, the phase cancelling circuit is electrically connected between a transmit port of the transmit filter and the antenna and between a receive port of the receive filter and the antenna.

In some embodiments, the techniques described herein relate to a method wherein the phase cancelling circuit includes a plurality of longitudinally coupled interdigital transducer electrodes.

In some embodiments, the techniques described herein relate to a method wherein the phase cancelling circuit is positioned within center fifty percent of the width.

In some embodiments, the techniques described herein relate to a method further including an acoustic wave obstacle in the acoustic track.

In some embodiments, the techniques described herein relate to a method further including a second filter circuit in electrical communication with the piezoelectric layer, and a second phase cancelling circuit integrated with the second filter circuit.

In some embodiments, the techniques described herein relate to a method wherein a second acoustic track of the second phase cancelling circuit extends between a third periphery portion and a fourth periphery portion of the sidewall, the second phase cancelling circuit is positioned within center seventy percent of a second width between the third periphery portion and the fourth periphery portion.

In some embodiments, the techniques described herein relate to an acoustic wave device wherein the first periphery portion is closer to the phase cancelling circuit than the second periphery portion, the phase cancelling circuit is spaced at least 200 micrometers from the first periphery portion.

In some aspects, the techniques described herein relate to a multi-layer piezoelectric substrate surface acoustic wave device including: a support substrate; a piezoelectric layer over the support substrate, the piezoelectric layer having a first side facing the support substrate, a second side opposite the first side, and a sidewall extending between the first side and the second side and defining a periphery of the piezoelectric layer, the sidewall tapered such that an angle between the second side and the sidewall is in a range between 15° and 80°; a filter circuit in electrical communication with the piezoelectric layer; and a phase cancelling circuit integrated with the filter circuit, an acoustic track of the phase cancelling circuit extending between a first periphery portion and a second periphery portion of the sidewall, the phase cancelling circuit being positioned within center seventy percent of a width between the first periphery portion and the second periphery portion.

In some aspects, the techniques described herein relate to a multi-layer piezoelectric substrate surface acoustic wave device including: a multi-layer piezoelectric substrate including a support substrate and a piezoelectric layer, the piezoelectric layer having a first side facing the support substrate, a second side opposite the first side, and a sidewall extending between the first side and the second side and defining a periphery of the piezoelectric layer, the sidewall tapered such that the first side is wider than the second side; a filter circuit including a plurality of resonators in electrical communication with the piezoelectric layer; and a phase cancelling circuit integrated with the filter circuit, an acoustic track of the phase cancelling circuit being offset from the plurality of resonators.

In some embodiments, the techniques described herein relate to an acoustic wave device wherein an angle between the second side and the sidewall is in a range between 15° and 80°.

In some embodiments, the techniques described herein relate to an acoustic wave device wherein the multi-layer piezoelectric substrate further includes a silicon oxide layer between the support substrate and the piezoelectric layer.

In some embodiments, the techniques described herein relate to an acoustic wave device wherein the filter circuit includes a transmit filter connected to an antenna and a receive filter connected to the antenna, the phase cancelling circuit is electrically connected between a transmit port of the transmit filter and the antenna and between a receive port of the receive filter and the antenna.

In some embodiments, the techniques described herein relate to an acoustic wave device wherein the phase cancelling circuit includes a plurality of longitudinally coupled interdigital transducer electrodes.

In some embodiments, the techniques described herein relate to an acoustic wave device further including an acoustic wave obstacle in the acoustic track.

In some embodiments, the techniques described herein relate to an acoustic wave device wherein the acoustic wave obstacle includes a reflector.

In some embodiments, the techniques described herein relate to an acoustic wave device further including a second filter circuit including a second plurality of resonators in electrical communication with the piezoelectric layer, and a second phase cancelling circuit integrated with the second filter circuit.

In some embodiments, the techniques described herein relate to an acoustic wave device wherein a second acoustic track of the second phase cancelling circuit being offset from the second plurality of resonators.

In some embodiments, the techniques described herein relate to an acoustic wave device wherein the acoustic track of the phase cancelling circuit being is free from the plurality of resonators.

In some aspects, the techniques described herein relate to a method of manufacturing a multi-layer piezoelectric substrate surface acoustic wave device, the method including: providing a multi-layer piezoelectric substrate including a support substrate and a piezoelectric layer, the piezoelectric layer having a first side facing the support substrate, a second side opposite the first side, and a sidewall extending between the first side and the second side and defining a periphery of the piezoelectric layer, the sidewall tapered such that the first side is wider than the second side; forming a filter circuit including a plurality of resonators in electrical communication with the piezoelectric layer; and providing a phase cancelling circuit integrated with the filter circuit, an acoustic track of the phase cancelling circuit being offset from the plurality of resonators.

In some embodiments, the techniques described herein relate to a method wherein an angle between the second side and the sidewall is in a range between 15° and 80°.

In some embodiments, the techniques described herein relate to a method wherein the multi-layer piezoelectric substrate further includes a silicon oxide layer between the support substrate and the piezoelectric layer.

In some embodiments, the techniques described herein relate to a method wherein the filter circuit includes a transmit filter connected to an antenna and a receive filter connected to the antenna, the phase cancelling circuit is electrically connected between a transmit port of the transmit filter and the antenna and between a receive port of the receive filter and the antenna.

In some embodiments, the techniques described herein relate to a method wherein the phase cancelling circuit includes a plurality of longitudinally coupled interdigital transducer electrodes.

In some embodiments, the techniques described herein relate to a method further including an acoustic wave obstacle in the acoustic track.

In some embodiments, the techniques described herein relate to a method wherein the acoustic wave obstacle includes a reflector.

In some embodiments, the techniques described herein relate to a method further including a second filter circuit including a second plurality of resonators in electrical communication with the piezoelectric layer, and a second phase cancelling circuit integrated with the second filter circuit.

In some embodiments, the techniques described herein relate to a method wherein a second acoustic track of the second phase cancelling circuit being offset from the second plurality of resonators.

In some embodiments, the techniques described herein relate to a method wherein the acoustic track of the phase cancelling circuit being is free from the plurality of resonators.

In some aspects, the techniques described herein relate to a multi-layer piezoelectric substrate surface acoustic wave device including: a multi-layer piezoelectric substrate including a support substrate and a piezoelectric layer, the piezoelectric layer having a first side facing the support substrate, a second side opposite the first side, and a sidewall extending between the first side and the second side and defining a periphery of the piezoelectric layer, the sidewall tapered such that the first side is wider than the second side; a filter circuit including a plurality of resonators in electrical communication with the piezoelectric layer; and a phase cancelling circuit integrated with the filter circuit, none of the plurality of resonators positioned in an acoustic track of the phase cancelling circuit.

In some aspects, the techniques described herein relate to a multi-layer piezoelectric substrate surface acoustic wave device including: a multi-layer piezoelectric substrate including a support substrate and a piezoelectric layer; a filter circuit including a plurality of resonators in electrical communication with the piezoelectric layer; a phase cancelling circuit integrated with the filter circuit, an acoustic track of the phase cancelling circuit being offset from the plurality of resonators; and an acoustic obstruction structure in the acoustic track of the phase cancelling circuit.

In some embodiments, the techniques described herein relate to an acoustic wave device wherein the acoustic obstruction structure includes a metal line having a reflection surface angled non-perpendicular with a wave propagation direction of the phase cancelling circuit.

In some embodiments, the techniques described herein relate to an acoustic wave device wherein the acoustic obstruction structure includes an elastic material.

In some embodiments, the techniques described herein relate to an acoustic wave device wherein the acoustic obstruction structure includes an angled electrical connection line that is angled non-perpendicular with a wave propagation direction of the phase cancelling circuit.

In some embodiments, the techniques described herein relate to an acoustic wave device wherein the acoustic obstruction structure includes a trench in the piezoelectric layer.

In some embodiments, the techniques described herein relate to an acoustic wave device wherein the acoustic obstruction structure includes a reflector.

In some embodiments, the techniques described herein relate to an acoustic wave device further including a second filter circuit including a second plurality of resonators in electrical communication with the piezoelectric layer, and a second phase cancelling circuit integrated with the second filter circuit.

In some embodiments, the techniques described herein relate to an acoustic wave device wherein a second acoustic track of the second phase cancelling circuit being free from the second plurality of resonators.

In some embodiments, the techniques described herein relate to an acoustic wave device wherein the multi-layer piezoelectric substrate further includes a silicon oxide layer between the support substrate and the piezoelectric layer.

In some embodiments, the techniques described herein relate to an acoustic wave device wherein the filter circuit includes a transmit filter connected to an antenna and a receive filter connected to the antenna.

In some embodiments, the techniques described herein relate to an acoustic wave device wherein the phase cancelling circuit is electrically connected between a transmit port of the transmit filter and the antenna and between a receive port of the receive filter and the antenna.

In some aspects, the techniques described herein relate to a method of manufacturing a multi-layer piezoelectric substrate surface acoustic wave device, the method including: providing a multi-layer piezoelectric substrate including a support substrate and a piezoelectric layer; forming a filter circuit including a plurality of resonators in electrical communication with the piezoelectric layer; providing a phase cancelling circuit integrated with the filter circuit, an acoustic track of the phase cancelling circuit being offset from the plurality of resonators; and providing an acoustic obstruction structure in the acoustic track of the phase cancelling circuit.

In some embodiments, the techniques described herein relate to a method wherein the acoustic obstruction structure includes a metal line having a reflection surface angled non-perpendicular with a wave propagation direction of the phase cancelling circuit.

In some embodiments, the techniques described herein relate to a method wherein the acoustic obstruction structure includes an elastic material.

In some embodiments, the techniques described herein relate to a method wherein the acoustic obstruction structure includes an angled electrical connection line that is angled non-perpendicular with a wave propagation direction of the phase cancelling circuit.

In some embodiments, the techniques described herein relate to a method wherein the acoustic obstruction structure includes a trench in the piezoelectric layer.

In some embodiments, the techniques described herein relate to a method wherein the acoustic obstruction structure includes a reflector.

In some embodiments, the techniques described herein relate to a method further including a second filter circuit including a second plurality of resonators in electrical communication with the piezoelectric layer, and a second phase cancelling circuit integrated with the second filter circuit, wherein a second acoustic track of the second phase cancelling circuit being free from the second plurality of resonators.

In some embodiments, the techniques described herein relate to a method wherein the multi-layer piezoelectric substrate further includes a silicon oxide layer between the support substrate and the piezoelectric layer.

In some embodiments, the techniques described herein relate to a method wherein the filter circuit includes a transmit filter connected to an antenna and a receive filter connected to the antenna, the phase cancelling circuit is electrically connected between a transmit port of the transmit filter and the antenna and between a receive port of the receive filter and the antenna.

In some aspects, the techniques described herein relate to a multi-layer piezoelectric substrate surface acoustic wave device including: a multi-layer piezoelectric substrate including a support substrate and a piezoelectric layer; a filter circuit including a plurality of resonators in electrical communication with the piezoelectric layer; a phase cancelling circuit integrated with the filter circuit, none of the plurality of resonators positioned in an acoustic track of the phase cancelling circuit; and an acoustic obstruction structure in the acoustic track of the phase cancelling circuit.

In some aspects, the techniques described herein relate to a multi-layer piezoelectric substrate surface acoustic wave device including: a multi-layer piezoelectric substrate including a support substrate and a piezoelectric layer; a filter circuit including a plurality of resonators in electrical communication with the piezoelectric layer; a phase cancelling circuit integrated with the filter circuit; and a pair of acoustic obstruction structures including a first acoustic obstruction structure and a second acoustic obstruction structure positioned such that the phase cancelling circuit is located between the pair of acoustic obstruction structures along an acoustic track of the phase cancelling circuit.

In some embodiments, the techniques described herein relate to an acoustic wave device wherein the first acoustic obstruction structure and the second acoustic obstruction structure include different structures.

In some embodiments, the techniques described herein relate to an acoustic wave device wherein the first acoustic obstruction structure includes a metal line having a reflection surface angled non-perpendicular with a wave propagation direction of the phase cancelling circuit.

In some embodiments, the techniques described herein relate to an acoustic wave device wherein the first acoustic obstruction structure includes an elastic material.

In some embodiments, the techniques described herein relate to an acoustic wave device wherein the first acoustic obstruction structure includes an angled electrical connection line that is angled non-perpendicular with a wave propagation direction of the phase cancelling circuit.

In some embodiments, the techniques described herein relate to an acoustic wave device wherein the first acoustic obstruction structure includes a trench in the piezoelectric layer.

In some embodiments, the techniques described herein relate to an acoustic wave device wherein the first acoustic obstruction structure includes a reflector.

In some embodiments, the techniques described herein relate to an acoustic wave device further including a second filter circuit including a second plurality of resonators in electrical communication with the piezoelectric layer, and a second phase cancelling circuit integrated with the second filter circuit.

In some embodiments, the techniques described herein relate to an acoustic wave device wherein the filter circuit includes a transmit filter connected to an antenna and a receive filter connected to the antenna.

In some embodiments, the techniques described herein relate to an acoustic wave device, wherein the phase cancelling circuit is electrically connected between a transmit port of the transmit filter and the antenna and between a receive port of the receive filter and the antenna.

In some aspects, the techniques described herein relate to a method of manufacturing a multi-layer piezoelectric substrate surface acoustic wave device, the method including: a multi-layer piezoelectric substrate including a support substrate and a piezoelectric layer; a filter circuit including a plurality of resonators in electrical communication with the piezoelectric layer; a phase cancelling circuit integrated with the filter circuit; and a pair of acoustic obstruction structures including a first acoustic obstruction structure and a second acoustic obstruction structure positioned such that the phase cancelling circuit is located between the pair of acoustic obstruction structures along an acoustic track of the phase cancelling circuit.

In some embodiments, the techniques described herein relate to a method wherein the first acoustic obstruction structure and the second acoustic obstruction structure include different structures.

In some embodiments, the techniques described herein relate to a method wherein the first acoustic obstruction structure includes a metal line having a reflection surface angled non-perpendicular with a wave propagation direction of the phase cancelling circuit.

In some embodiments, the techniques described herein relate to a method wherein the first acoustic obstruction structure includes an elastic material.

In some embodiments, the techniques described herein relate to a method wherein the first acoustic obstruction structure includes an angled electrical connection line that is angled non-perpendicular with a wave propagation direction of the phase cancelling circuit.

In some embodiments, the techniques described herein relate to a method wherein the first acoustic obstruction structure includes a trench in the piezoelectric layer.

In some embodiments, the techniques described herein relate to a method wherein the first acoustic obstruction structure includes a reflector.

In some embodiments, the techniques described herein relate to a method further including a second filter circuit including a second plurality of resonators in electrical communication with the piezoelectric layer, and a second phase cancelling circuit integrated with the second filter circuit.

In some embodiments, the techniques described herein relate to a method wherein the filter circuit includes a transmit filter connected to an antenna and a receive filter connected to the antenna.

In some embodiments, the techniques described herein relate to a method wherein the phase cancelling circuit is electrically connected between a transmit port of the transmit filter and the antenna and between a receive port of the receive filter and the antenna.

In some aspects, the techniques described herein relate to a multi-layer piezoelectric substrate surface acoustic wave device including: a multi-layer piezoelectric substrate including a support substrate and a piezoelectric layer; a filter circuit including a plurality of resonators in electrical communication with the piezoelectric layer; a first acoustic obstruction structure; a second acoustic obstruction structure; and a phase cancelling circuit integrated with the filter circuit and positioned between the first acoustic obstruction structure and the second acoustic obstruction structure.

The present disclosure relates to U.S. patent application Ser. No. ______ [Attorney Docket SKYWRKS.1529A1], titled “MULTI-LAYER PIEZOELECTRIC SUBSTRATE SURFACE ACOUSTIC WAVE DEVICE WITH PHASE CANCELLING CIRCUIT,” U.S. patent application Ser. No. ______ [Attorney Docket SKYWRKS.1529A3], titled “INTERFERENCE SUPPRESSION STRUCTURE FOR PHASE CANCELLING CIRCUIT IN MULTI-LAYER PIEZOELECTRIC SUBSTRATE SURFACE ACOUSTIC WAVE DEVICE,” and U.S. patent application Ser. No. ______ [Attorney Docket SKYWRKS.1529A4], titled “PHASE CANCELLING CIRCUIT IN MULTI-LAYER PIEZOELECTRIC SUBSTRATE SURFACE ACOUSTIC WAVE DEVICE WITH INTERFERENCE SUPPRESSION STRUCTURE,” filed on even date herewith, the entire disclosure of which is hereby incorporated by reference herein.

### BRIEF DESCRIPTION OF THE DRAWINGS

Embodiments of this disclosure will now be described, by way of non-limiting example, with reference to the accompanying drawings.

FIG. 1A is a circuit layout of a multi-layer piezoelectric substrate (MPS) surface acoustic wave (SAW) device according to an embodiment.

FIG. 1B is a schematic cross-sectional side view of the MPS-SAW device shown in FIG. 1A.

FIG. 2 is a circuit layout of a multi-layer piezoelectric substrate (MPS) surface acoustic wave (SAW) device assembly according to an embodiment.

FIG. 3 is a graph showing simulated isolation plot of the MPS-SAW device of the MPS-SAW device assembly with and without a phase cancelling circuit.

FIG. 4 is a circuit layout of a multi-layer piezoelectric substrate (MPS) surface acoustic wave (SAW) device assembly.

FIG. 5 is a graph showing simulated isolation plot of the MPS-SAW device of FIG. 1A and the MPS-SAW device of FIG. 4.

FIG. 6 is a circuit layout of a multi-layer piezoelectric substrate (MPS) surface acoustic wave (SAW) device assembly.

FIG. 7 is a graph showing simulated isolation plot of the MPS-SAW device of FIG. 1A and the MPS-SAW device of FIG. 6.

FIG. 8A is a circuit layout of a multi-layer piezoelectric substrate (MPS) surface acoustic wave (SAW) device assembly according to an embodiment.

FIG. 8B is a zoomed-in view of FIG. 8A.

FIG. 9A is a schematic top plan view of a portion of a multi-layer piezoelectric substrate (MPS) surface acoustic wave (SAW) device that includes acoustic obstacles according to an embodiment.

FIG. 9B is a schematic top plan view of a portion of a multi-layer piezoelectric substrate (MPS) surface acoustic wave (SAW) device that includes an acoustic obstacle according to another embodiment.

FIG. 9C is a schematic top plan view of a portion of a multi-layer piezoelectric substrate (MPS) surface acoustic wave (SAW) device that includes an angled electrical connection line according to another embodiment.

FIG. 9D is a schematic top plan view of a portion of a multi-layer piezoelectric substrate (MPS) surface acoustic wave (SAW) device that includes an acoustic obstacle according to another embodiment.

FIG. 9E is a cross-sectional side view of FIG. 9D.

FIG. 10 is a schematic top plan view of a portion of a multi-layer piezoelectric substrate (MPS) surface acoustic wave (SAW) device that includes a reflector according to an embodiment.

FIG. 11 is a schematic diagram of a radio frequency module that includes a surface acoustic wave resonator according to an embodiment.

FIG. 12 is a schematic diagram of a radio frequency module that includes filters with surface acoustic wave resonators according to an embodiment.

FIG. 13 is a schematic block diagram of a module that includes an antenna switch and duplexers that include a surface acoustic wave resonator according to an embodiment.

FIG. 14A is a schematic block diagram of a module that includes a power amplifier, a radio frequency switch, and duplexers that include a surface acoustic wave resonator according to an embodiment.

FIG. 14B is a schematic block diagram of a module that includes filters, a radio frequency switch, and a low noise amplifier according to an embodiment.

FIG. 15A is a schematic block diagram of a wireless communication device that includes a filter with a surface acoustic wave resonator in accordance with one or more embodiments.

FIG. 15B is a schematic block diagram of another wireless communication device that includes a filter with a surface acoustic wave resonator in accordance with one or more embodiments.

### DETAILED DESCRIPTION

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

Acoustic wave filters can filter radio frequency (RF) signals in a variety of applications, such as in an RF front end of a mobile phone. An acoustic wave filter can be implemented with surface acoustic wave (SAW) devices. Certain SAW devices may be referred to as SAW resonators. Any features of the SAW resonators discussed herein can be implemented in any suitable SAW device such as a multi-layer piezoelectric substrate (MPS) SAW device.

In general, high quality factor (Q), large effective electromechanical coupling coefficient (k2), high frequency ability, and spurious free response can be significant aspects for acoustic wave elements to enable low-loss filters, delay lines, stable oscillators, and sensitive sensors. Also, high power durability can be a significant aspect for enabling reliable SAW devices. MPS-SAW devices can achieve greater performance than TC-SAW devices in some aspects. For example, the MPS structures can enable relatively low loss, high isolation, high Q, and high k2 acoustic wave devices as compared to TC-SAW devices.

In acoustic wave devices (e.g., surface acoustic wave filters), phase cancellation can be used to achieve high isolation. For example, a filter can include a delay line as a cancelling circuit (e.g., phase cancelling circuit) for cancelling signal leakage between a terminal and another terminal (e.g., between a transmission terminal and a reception terminal) to improve the isolation of the filter. The phase cancelling circuit can include a loop circuit. It can be critical for a phase cancelling circuit to generate an accurate signal to compensate for the main filter response, and the phase cancelling circuit can be sensitive to interferences. Any unwanted acoustic waves, such as an acoustic wave reflection from an edge of a piezoelectric layer and a coupling with other interdigital transducer electrodes in the same acoustic wave device can deteriorate the performance of the phase cancelling circuit.

Various embodiments disclosed herein relate to a multi-layer piezoelectric substrate surface acoustic wave MPS-SAW devices (e.g., filters) with a phase cancelling circuit (e.g., a loop circuit) with reduced interference. The interference can be caused by acoustic energy reflection back to the phase cancelling circuit and/or acoustic coupling between the phase cancelling circuit and a resonator in the filter. Filters according to some embodiments can include an interference suppression structure, such as a reflection suppression structure or a coupling suppression structure. For example, a piezoelectric layer can have a shape, such as a tapered sidewall, that can prevent or mitigate the wave generated in the phase cancelling circuit to reflect back to the phase cancelling circuit. The interference can also be prevented or mitigated by properly locating or positioning the phase cancelling circuit. For example, the phase cancelling circuit can be positioned such that an acoustic track of the phase cancelling circuit is offset from the resonators of the MPS-SAW device. For another example, the phase cancelling circuit can be sufficiently spaced from an edge or a portion of the sidewall of the piezoelectric layer that is in the acoustic track of the phase cancelling circuit.

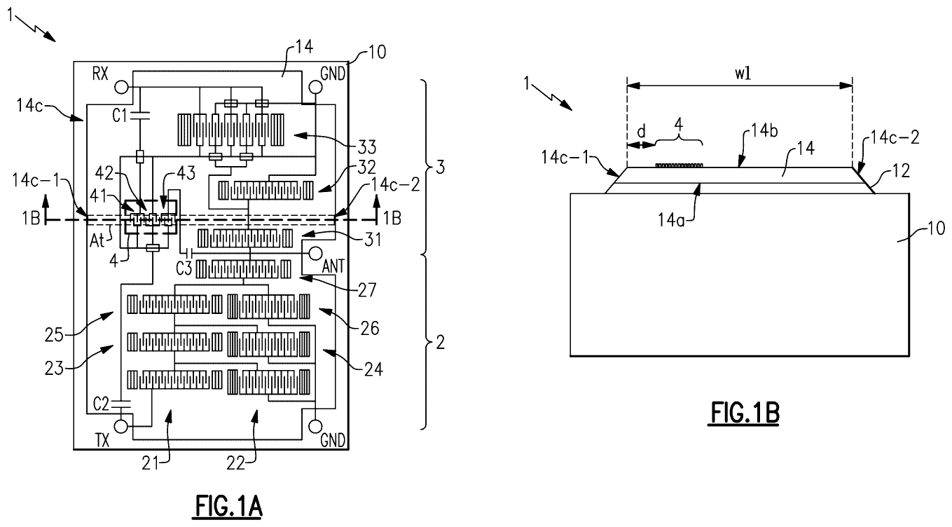

FIG. 1A is a circuit layout of a multi-layer piezoelectric substrate (MPS) surface acoustic wave (SAW) device 1 according to an embodiment. FIG. 1B is a schematic cross-sectional side view of the MPS-SAW device 1 shown in FIG. 1A. The MPS-SAW device 1 can be an example of a duplexer. The MPS-SAW device I can include a first filter 2, a second filter 3, and a phase cancelling circuit 4 (e.g., a loop circuit). For example, the first filter 2 can be a transmit filter and the second filter 3 can be a receive filter. The MPS-SAW device 1 can include a support substrate 10, an intermediate layer 12, a piezoelectric layer 14, and one or more resonators. The resonators can be in electrical communication with the piezoelectric layer 14.

The support substrate 10 can be any suitable substrate layer, such as a silicon layer, a quartz layer, a ceramic layer, a glass layer, a spinel layer, a magnesium oxide spinel layer, a sapphire layer, a diamond layer, a silicon carbide layer, a silicon nitride layer, an aluminum nitride layer, an aluminum oxide layer, or the like. The support substrate 10 can have a relatively high acoustic impedance. For example, the support substrate 10 can have a higher impedance than an impedance of the piezoelectric layer 14 and a higher thermal conductivity than a thermal conductivity of the piezoelectric layer 14. In some embodiments, there can be a trap rich layer that may be formed at or near a surface of the support substrate 10 facing the intermediate layer 12. One or more additional layers can be inserted or positioned between the intermediate layer 12 and the support substrate 10 to prevent or mitigate the unwanted electrical leakage on the surface of the support substrate 10. For example, one or more layers that include Poly-Si, Amorphas Si, Porous Si, SiN, and/or AlN can be disposed or provided between the intermediate layer 12 and the support substrate 10.

The illustrated MPS-SAW device 1 includes the intermediate layer 12 between the support substrate 10 and the piezoelectric layer 14. The intermediate layer 12 can be, for example, a single crystal layer. The intermediate layer 12 can also be referred to as a functional layer. In some embodiments, the intermediate layer 12 can be a silicon oxide layer (e.g., a silicon dioxide (SiO₂) layer. In some embodiment, the intermediate layer 12 can function as an adhesion layer. In some embodiments, a thickness of the intermediate layer 12 can be the same as, generally similar to, or thinner than the thickness of the piezoelectric layer 14.

The piezoelectric layer 14 can include any suitable piezoelectric layer, such as a lithium based piezoelectric layer. In some embodiments, the piezoelectric layer 14 can be a lithium tantalate (LT) layer. For example, the piezoelectric layer 14 can be an LT layer having a cut angle of 20° (20° Y-cut X-propagation LT) or a cut angle of 60° (60° Y-cut X-propagation LT). For example, the piezoelectric layer 14 can be 20±10° Y-cut LT, 42±25° Y-cut LT, 42±20° Y-cut LT, 42±15° Y-cut LT, 42±10° Y-cut LT, 42±5° Y-cut LT, 60±20° Y-cut LT, 60±15° Y-cut LT, 60±10° Y-cut LT, or 60±5° Y-cut LT. Any other suitable piezoelectric material, such as a lithium niobate (LN) layer, can be used as the piezoelectric layer 14. For example, the piezoelectric layer 14 can be an LN layer having a cut angle of about 118° (118° Y-cut X-propagation LN) or more or a cut angle of about 132° (132Y-cut X-propagation LN) or less. For example, the piezoelectric layer 14 can be 125±20° Y-cut LN, 125±15° Y-cut LN, 125±10° Y-cut LN, or 125±5° Y-cut LN. A thickness of the piezoelectric layer 14 can be selected based on a wavelength λ or L of a surface acoustic wave generated by the MPS-SAW device 1 in certain applications. In some embodiments, the wavelength L can be in a range between, for example, 3 micrometers and 6 micrometers, 3.5 micrometers and 6 micrometers, 3 micrometers and 5.5 micrometers, or 3.5 micrometers and 5.5 micrometers. The piezoelectric layer 14 can be sufficiently thick to avoid significant frequency variation. For example, the thickness of the piezoelectric layer 14 can be in a range of 0.1 L to 0.5, 0.1 L to 0.3 L, or 0.1 L to 0.2 L. Selecting the thickness of the piezoelectric layer 14 from these ranges can be critical in avoiding significant frequency variation and providing sufficient temperature coefficient of frequency for the MPS-SAW device 1. In some embodiments, the piezoelectric layer 14 can include lithium tantalate (LT) and lithium niobate (LN).

The resonators can include first to seventh resonators 21, 22, 23, 24, 25, 26, 27 included in the first filter 2, and eight to tenth resonators 31, 32, 33 included in the second filter 3. The first to nineth resonators 21-27, 31, 32 can each include an interdigital transducer (IDT) electrode and a pair of reflectors. The tenth resonator 33 can include a plurality of IDT electrodes (e.g., fine IDT electrodes in the illustrated embodiment) coupled longitudinally between a pair of reflectors. The tenth resonator 33 can be an example of a multimode surface acoustic wave resonator.

The first filter 2 and the second filter 3 can be connected to a common node, such as an antenna port ANT. The first filter 2 can be connected between the antenna port ANT and a terminal, such as a transmit port TX. The second filter 3 can be connected between the antenna port ANT and another terminal, such as a receive port RX. The first and second filters 2, 3 can also have respective ground ports GND.

The phase cancelling circuit 4 can include a plurality of interdigital transducer (IDT) electrodes, such as a first to third IDT electrodes 41, 42, 43, that are longitudinally coupled along a wave propagation direction or an acoustic track of the IDT electrodes. The phase cancelling circuit 4 can be integrated with the first filter 2 and the second filter 3. For example, the phase cancelling circuit 4 can be connected between the transmit port TX and the antenna port ANT and between the receive port RX and the antenna port ANT. The phase cancelling circuit 4 can reduce or cancel signal leakage between a terminal and another terminal (e.g., between the transmit port TX and the antenna port ANT and/or the receive port RX and the antenna port ANT) to improve the isolation of the filter (e.g., the first filter 2 and/or the second filter 3). The MPS-SAW device 1 can also include a capacitor C1 between the first IDT electrode 41 and the receive port RX, a capacitor C2 between the second IDT electrode and the transmit port TX, and a capacitor C3 between the third IDT electrode 43 and the antenna port ANT.

The IDT electrodes of the first to tenth resonators 21-27, 31-33 and the IDT electrodes 41, 42, 43 can include any suitable IDT electrode material. For example, the IDT electrode material can include molybdenum (Mo), aluminum (Al), copper (Cu), Magnesium (Mg), titanium (Ti), tungsten (W), the like, or any suitable combination thereof. The IDT electrode material may include alloys, such as AlMgCu, AlCu, etc. In some embodiments, the IDT electrodes of the first to tenth resonators 21-27, 31-33 and the IDT electrodes 41, 42, 43 can have a multi-layer structure that includes two or more layers. The interdigital transducer electrodes can be formed with (e.g., formed on or at least partially in) the piezoelectric layer 14. The piezoelectric layer 14 and the interdigital transducer electrodes can be provided in any suitable manner. For example, the piezoelectric layer 14 and the interdigital transducer electrodes can be provided in sequence. When the interdigital transducer electrode is provided at least partially in the piezoelectric layer 14, the piezoelectric layer 14 can be partially etched and/or provided in a plurality of steps.

Various features of the MPS-SAW device 1 enable the phase cancelling circuit 4 to operate with reduced interference. The piezoelectric layer 14 can have a shape, such as a tapered sidewall, that can prevent or mitigate the wave generated in the phase cancelling circuit 4 to reflect back to the phase cancelling circuit 4. The phase cancelling circuit 4 can be positioned such that an acoustic track At is offset from the resonators of the MPS-SAW device 1. For example, none of the plurality of resonators can be positioned in the acoustic track At of the phase cancelling circuit 4. The phase cancelling circuit 4 can be sufficiently spaced from an edge or a portion of the sidewall of the piezoelectric layer 14 that is in the acoustic track At of the phase cancelling circuit 4.

The piezoelectric layer 14 has a first side 14a facing the intermediate layer 12 and the support substrate 10, a second side 14b opposite the first side 14a, and a sidewall 14c that extends between the first side 14a and the second side 14b. The sidewall 14c can be angled or tapered with an angle between the first side 14a and the sidewall 14c less than 90° and an angle between the second side 14b and the sidewall 14c greater than 90° such that the first side 14a is wider than the second side 14b. For example, the angle between the first side 14a and the sidewall 14c can be in a range between 15° and 80°, 15° and 75°, 25° and 75°, 35° and 75°, 25° and 65°, 35° and 65°, or 45° and 80°. The sidewall 14c with a tapered angle in these ranges can reflect acoustic energy in a direction that can prevent or mitigate unwanted reflection back to the phase cancelling circuit 4. Therefore, the sidewall 14c with the tapered angle can prevent or mitigate the phase cancelling circuit 4 from being interfered by the acoustic reflection from the edge or the sidewall 14c in the acoustic track At of the phase cancelling circuit 4. In some embodiments, the sidewall 14c may not be a straight sidewall. For example, the sidewall 14c can have a curvature.

The tapered sidewall 14c is an example of a reflection suppression structure. Various embodiments in accordance with principles and advantages disclosed herein can include any other suitable reflection suppression structures at the sidewall 14c in the acoustic track At of the phase cancelling circuit 4.

The acoustic track At of the phase cancelling circuit 4 can be offset from the resonators 21-27, 31-33 of the MPS-SAW device 1. In some embodiments, there is no resonator positioned in the acoustic track At of the phase cancelling circuit 4 and the acoustic track At can be free from the resonators 21-27, 31-33. For example, the acoustic track At of the phase cancelling circuit 4 does not overlap with any of the resonators 21-27, 31-33 of the MPS-SAW device 1.

The phase cancelling circuit 4 can be sufficiently spaced from the portion of the sidewall 14c of the piezoelectric layer 14 that is in the acoustic track At of the phase cancelling circuit 4. The phase cancelling circuit 4 can be positioned between two portions (e.g., a first portion 14c-1 and a second portion 14c-2) of the sidewall 14c in the acoustic track At. A width w1 extends between the first portion 14c-1 and the second portion 14c-2 of the sidewall 14c, and the phase cancelling circuit 4 is spaced from one of the portions closer to the phase cancelling circuit 4 (e.g., the first portion 14c-1 in the illustrated embodiment) of the sidewall 14c by a distance d. In some embodiments, the distance d between the phase cancelling circuit 4 and the first portion 14c-1 of the sidewall 14c can be 200 micrometers or more, 250 micrometers or more, or 300 micrometers or more. For example, the distance d can be in a range between 200 micrometers and 500 micrometers, or 250 micrometers and 500 micrometers. In some embodiments, the distance d between the phase cancelling circuit 4 and the first portion 14c-1 of the sidewall 14c can be 10% of the width w1 or more, 20% of the width w1 or more, 30% of the width w1 or more, 40% of the width w1 or more, 50% of the width w1 or more, or 70% of the width w1 or more. For example, the phase cancelling circuit 4 can be positioned within center seventy percent (70%), within center fifty percent (50%), or center twenty-five percent (25%) of the width w1.

The principles and advantages disclosed herein can be implemented in any other suitable types of filters. For example, the features disclosed herein can be implemented with an MPS-SAW device that includes a plurality of separate filters formed on a single piezoelectric layer.

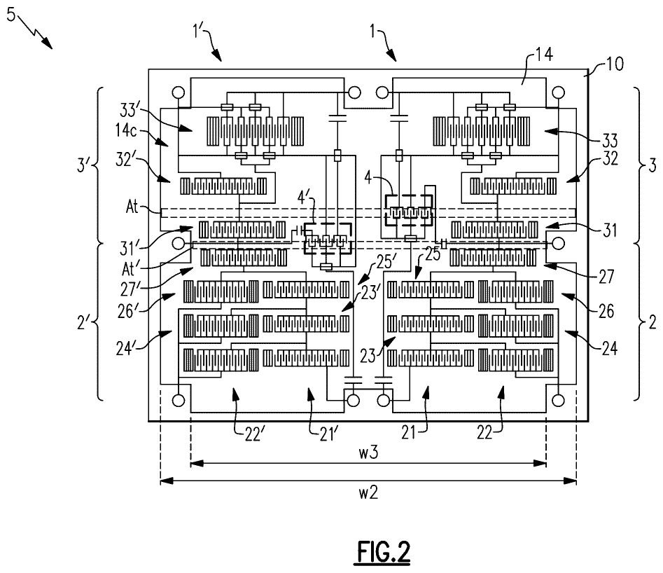

FIG. 2 is a circuit layout of a multi-layer piezoelectric substrate (MPS) surface acoustic wave (SAW) device assembly 5 according to an embodiment. Unless otherwise noted, the components of the MPS-SAW device assembly 5 shown in FIG. 2 may be structurally and/or functionally the same as or generally similar to like components disclosed herein. The MPS-SAW device assembly 5 can include the MPS-SAW device 1 illustrated in FIGS. 1A and 1B and an MPS-SAW device 1′. The MPS-SAW device 1′ can be generally similar to the MPS-SAW device 1. The MPS-SAW devices 1, 1′ can be examples of duplexers. The MPS-SAW device 1 can include a first filter 2, a second filter 3, and a phase cancelling circuit 4 (e.g., a loop circuit), and the MPS-SAW device 1′ can include a third filter 2′, a fourth filter 3′, and a phase cancelling circuit 4′ (e.g., a loop circuit). For example, the first and third filters 2, 2′ can be transmit filters and the second and fourth filters 3, 3′ can be receive filters. The MPS-SAW device assembly 5 can include a support substrate 10, a piezoelectric layer 14, and resonators 21-27, 31-33, 21′-27′, 31′-33′. The MPS-SAW device assembly 5 can also include an intermediate layer 12 between the support substrate 10 and the piezoelectric layer.

As with the MPS-SAW device 1 of FIGS. 1A and 1B, various features of the MPS-SAW device assembly 5 enable the phase cancelling circuit 4, 4′ to operate with reduced interference.

The piezoelectric layer 14 has a sidewall 14c that is tapered as described with respect to FIGS. 1A and 1B. The sidewall 14c with the tapered angle can prevent or mitigate the phase cancelling circuits 4, 4′ from being interfered by the acoustic reflection from the edge or the sidewall 14c in the acoustic tracks At, At′ of the phase cancelling circuits 4, 4′. The tapered sidewall 14c is an example of a reflection suppression structure. Various embodiments in accordance with principles and advantages disclosed herein can include any other suitable reflection suppression structures at the sidewall 14c in the acoustic track At of the phase cancelling circuit 4.

The acoustic tracks At, At′ of the phase cancelling circuits 4, 4′ can be offset from the resonators 21-27, 31-33, 21′-27′, 31′-33′ of the MPS-SAW device assembly 5. In some embodiments, there is no resonator positioned in the acoustic track At of the phase cancelling circuit 4. For example, the acoustic tracks At, At′ of the phase cancelling circuits 4, 4′ do not overlap with any of the resonators 21-27, 31-33, 21′-27′, 31′-33′.

The phase cancelling circuits 4, 4′ can be sufficiently spaced from portions of the sidewall 14c of the piezoelectric layer 14 that are in the respective acoustic tracks At, At′ of the phase cancelling circuits 4, 4′. The phase cancelling circuits 4, 4′ can be positioned between two portions of the sidewall 14c in the respective acoustic tracks At, At′. A width w2 extends between the two portions of the sidewall 14c in the acoustic track At, and the phase cancelling circuit 4 is spaced from the portions of the sidewall 14c. A width w3 extends between the two portions of the sidewall 14c in the acoustic track At′, and the phase cancelling circuit 4′ is spaced from the portions of the sidewall 14c. In some embodiments, a distance between the phase cancelling circuit 4. 4′ and the sidewall 14c can be 200 micrometers or more, 250 micrometers or more, or 300 micrometers or more. For example, the distance can be in a range between 200 micrometers and 500 micrometers, or 250 micrometers and 500 micrometers. In some embodiments, the distance between the phase cancelling circuit 4 and the sidewall 14c can be 10% of the width w2 or more, 20% of the width w2 or more, 30% of the width w2 or more, 40% of the width w2 or more, 50% of the width w2 or more, or 70% of the width w2 or more. In some embodiments, the distance between the phase cancelling circuit 4′ and the sidewall 14c can be 10% of the width w3 or more, 20% of the width w3 or more, 30% of the width w3 or more, 40% of the width w3 or more, 50% of the width w3 or more, or 70% of the width w3 or more. For example, the phase cancelling circuit 4, 4′ can be positioned within center 70%, within center 50%, or center 25% of the respective widths w2, w3.

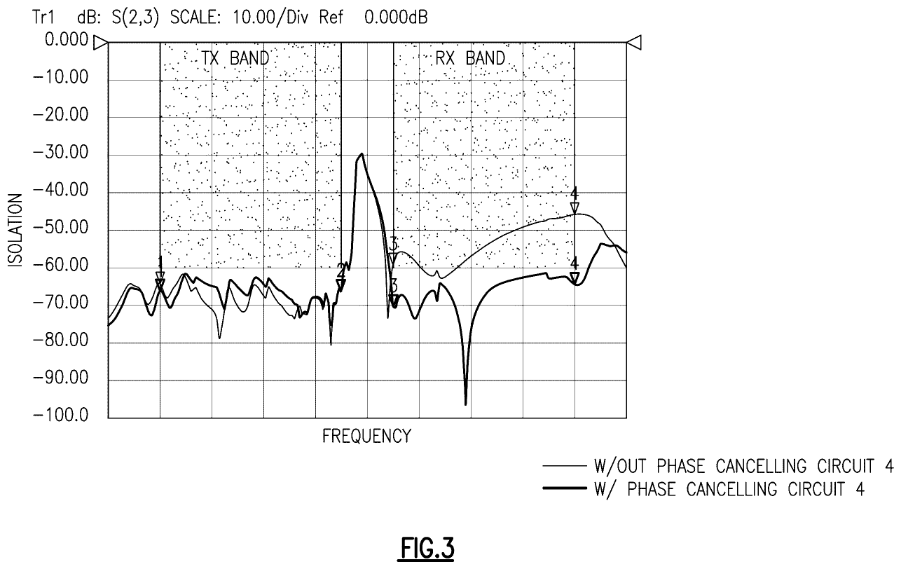

FIG. 3 is a graph showing simulated isolation plot of the MPS-SAW device 1 of the MPS-SAW device assembly 5 with and without the phase cancelling circuit 4. The simulation results indicate that the phase cancelling circuit 4 of the MPS-SAW device 1 can contribute to improving the isolation performance.

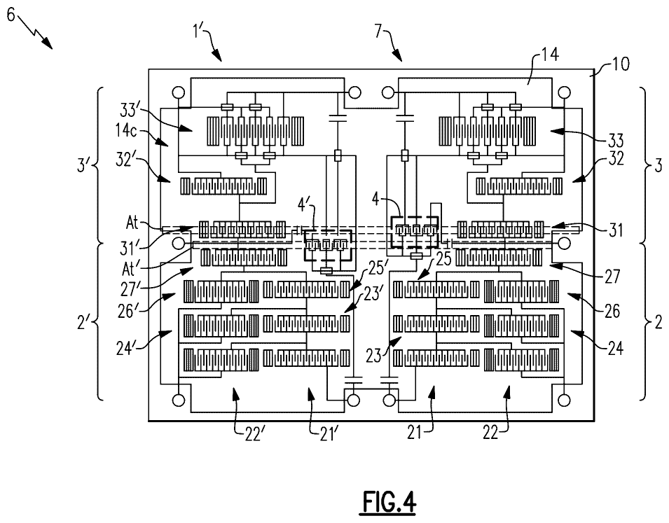

FIG. 4 is a circuit layout of a multi-layer piezoelectric substrate (MPS) surface acoustic wave (SAW) device assembly 6. Unless otherwise noted, the components of the MPS-SAW device assembly 6 shown in FIG. 4 may be structurally and/or functionally the same as or generally similar to like components disclosed herein. The MPS-SAW device assembly 6 includes the MPS-SAW device 1′ and an MPS-SAW device 7. The MPS-SAW device assembly 6 is similar to the MPS-SAW device assembly 5 of FIG. 2. However, in the MPS-SAW device assembly 6, the eighth resonator 31 and the eight resonator 31′ are positioned in the acoustic track At of the phase cancelling circuit 4.

FIG. 5 is a graph showing simulated isolation plot of the MPS-SAW device 1 of the MPS-SAW device assembly 5 and the MPS-SAW device 7 of the MPS-SAW device assembly 6. The simulation results indicate that when a resonator is positioned in the acoustic track At of the phase cancelling circuit 4, the isolation performance can be degraded by acoustic coupling between the phase cancelling circuit 4 and the resonator.

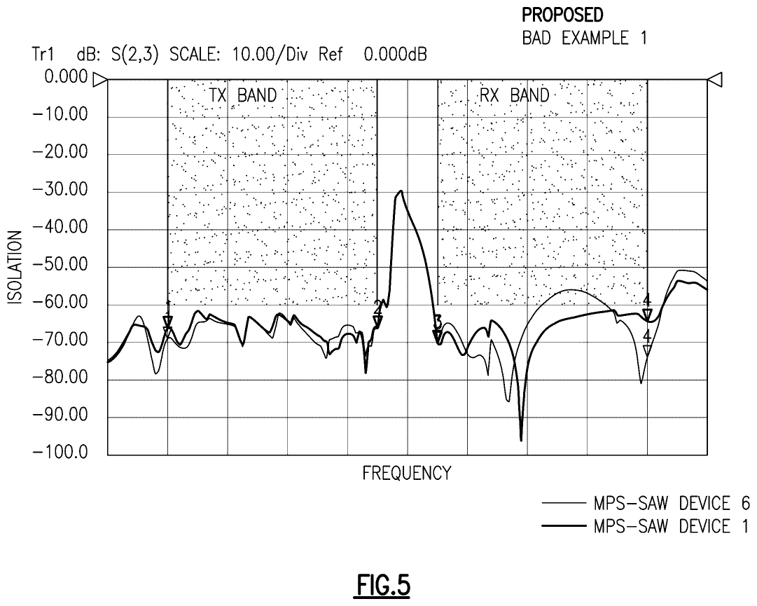

FIG. 6 is a circuit layout of a multi-layer piezoelectric substrate (MPS) surface acoustic wave (SAW) device assembly 6′. Unless otherwise noted, the components of the MPS-SAW device assembly 6′ shown in FIG. 6 may be structurally and/or functionally the same as or generally similar to like components disclosed herein. The MPS-SAW device assembly 6′ includes the MPS-SAW device 1′ and an MPS-SAW device 7′. The MPS-SAW device assembly 6′ is similar to the MPS-SAW device assembly 5 of FIG. 2. However, in the MPS-SAW device assembly 6, the phase cancelling circuit 4 is positioned near a periphery or a sidewall 14c of the piezoelectric layer 14. The phase cancelling circuit 4 is not sufficiently spaced from the sidewall 14c.

FIG. 7 is a graph showing simulated isolation plot of the MPS-SAW device 1 of the MPS-SAW device assembly 5 and the MPS-SAW device 7′ of the MPS-SAW device assembly 6′. The simulation results indicate that when the phase cancelling circuit 4 is positioned close to (e.g., less than 200 micrometers from) the sidewall 14c that is in the acoustic track At of the phase cancelling circuit 4, the isolation performance can be degraded by unwanted acoustic wave reflected back to the phase cancelling circuit 4 from the sidewall 14c.

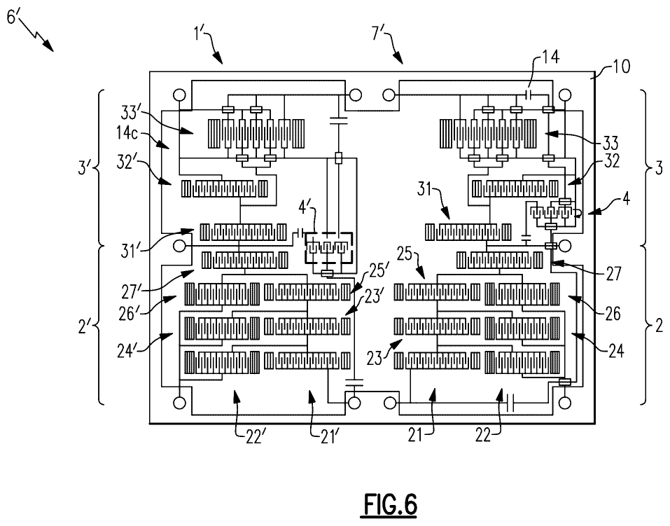

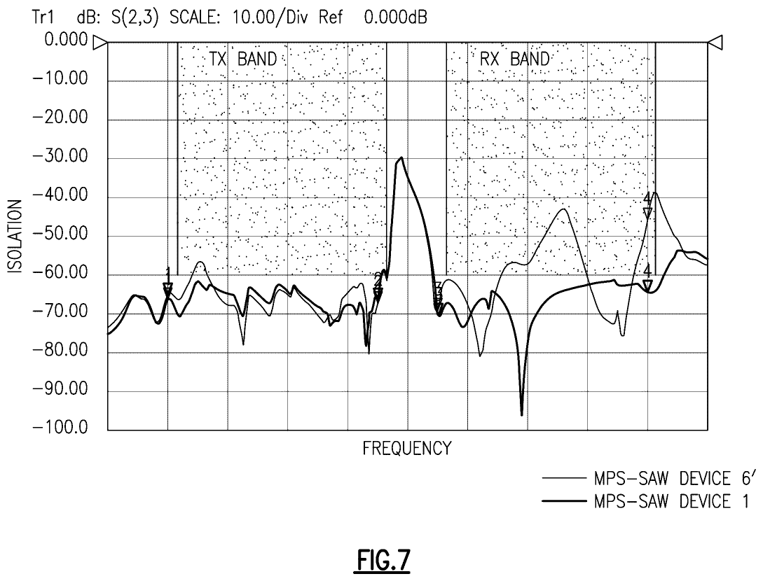

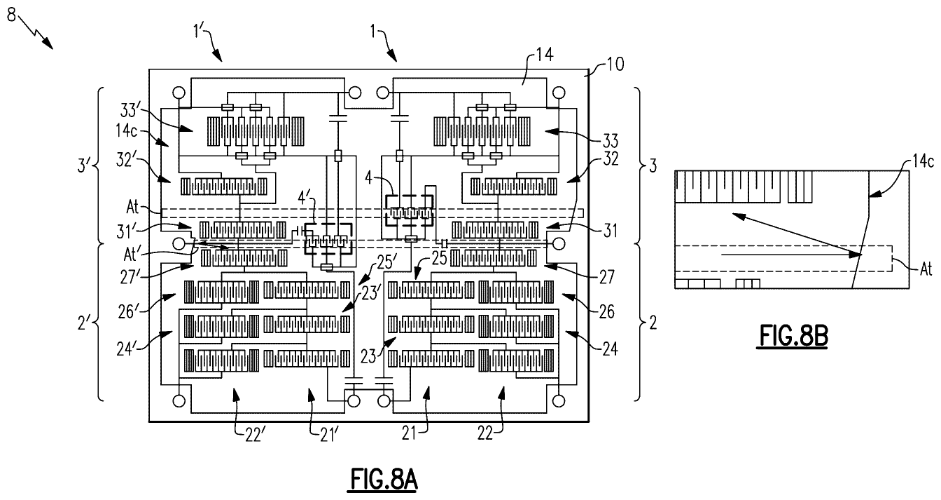

The simulation results of FIGS. 3, 5, and 7 indicate that appropriately positioning the phase cancelling circuit 4 and/or appropriately providing reflection suppression structures can be significant for reducing interference as disclosed herein and can improve the isolation performance of the filters. FIGS. 8A-10 show example reflection suppression structures that can prevent or mitigate unwanted interference.

FIG. 8A is a circuit layout of a multi-layer piezoelectric substrate (MPS) surface acoustic wave (SAW) device assembly 8. FIG. 8B is a zoomed-in view of a portion in FIG. 8A. Unless otherwise noted, the components of the MPS-SAW device assembly 8 shown in FIGS. 8A and 8B may be structurally and/or functionally the same as or generally similar to like components disclosed herein. The MPS-SAW device assembly 8 is generally similar to the MPS-SAW device assembly 5 of FIG. 2 except that in the MPS-SAW device assembly 8, the sidewall 14c of the piezoelectric layer 14 is angled such that a portion of the sidewall 14c in the acoustic track At is non-perpendicular with a wave propagation direction of the phase cancelling circuit 4. An arrow that extends horizontally in the acoustic track At in FIG. 8B represents the wave propagation direction of the phase cancelling circuit 4 and another arrow that extends from the end of the wave propagation direction arrow represents a reflected wave propagation direction. The angled sidewall 14c angled non-perpendicular with the wave propagation direction can prevent or mitigate the acoustic wave to reflect back to the phase cancelling circuit 4.

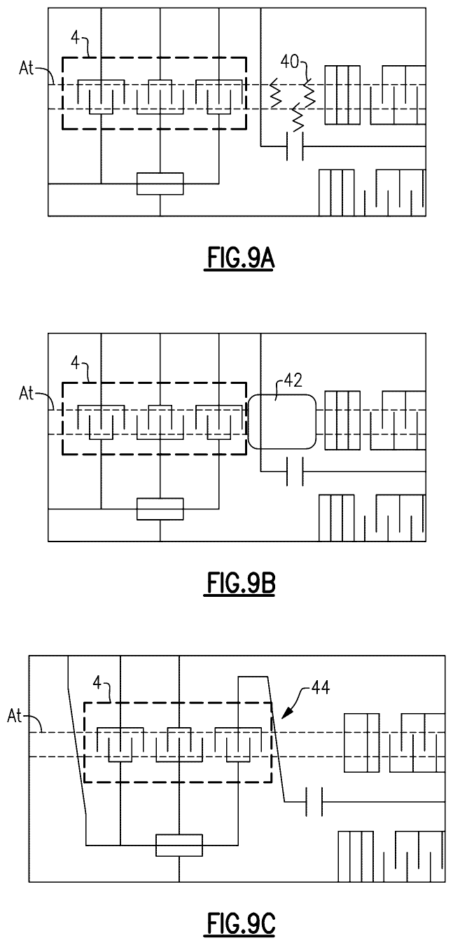

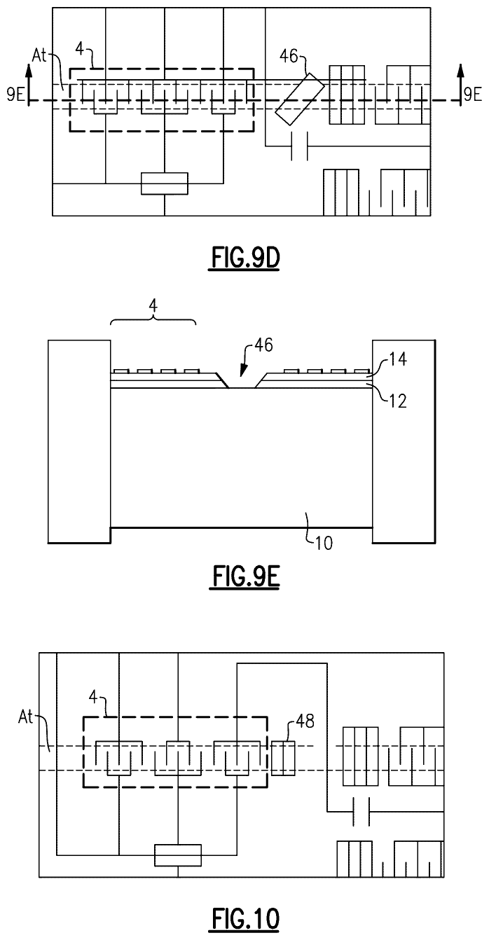

FIG. 9A is a schematic top plan view of a portion of a multi-layer piezoelectric substrate (MPS) surface acoustic wave (SAW) device that includes acoustic obstacles 40. Unless otherwise noted, the components shown in FIG. 9A may be structurally and/or functionally the same as or generally similar to like components disclosed herein. In some embodiments, the acoustic obstacles 40 can include a metal line, or any other suitable obstacle. For example, the acoustic obstacles 40 can include the same material as that of the resonators included in the MPS-SAW device. The acoustic obstacles can have a reflection surface angled non-perpendicular with the wave propagation direction of the phase cancelling circuit 4. The acoustic obstacles 40 can contribute to reducing and/or eliminating acoustic coupling between the phase cancelling circuit 4 and a resonator in the acoustic track At of the phase cancelling circuit 4. The acoustic obstacles 40 can absorb and/or scatter acoustic energy. The acoustic obstacles 40 can enable one or more resonators to be positioned in the acoustic track At.

FIG. 9B is a schematic top plan view of a portion of a multi-layer piezoelectric substrate (MPS) surface acoustic wave (SAW) device that includes an acoustic obstacle 42. Unless otherwise noted, the components shown in FIG. 9B may be structurally and/or functionally the same as or generally similar to like components disclosed herein. The acoustic obstacle 42 can function in a similar manner as the acoustic obstacles 40 of FIG. 9A. In some embodiments, the acoustic obstacles 42 can include an elastic material, such as a material that can be used for three dimensional (3D) bridge or packaging cavity for packaging the MPS-SAW device. The elastic material can absorb the acoustic wave from the phase cancelling circuit 4 or a resonator in the MPS-SAW device. The acoustic obstacles 42 can enable one or more resonators to be positioned in the acoustic track At.

FIG. 9C is a schematic top plan view of a portion of a multi-layer piezoelectric substrate (MPS) surface acoustic wave (SAW) device that includes an angled electrical connection line 44. Unless otherwise noted, the components shown in FIG. 9C may be structurally and/or functionally the same as or generally similar to like components disclosed herein. The angled electrical connection line 44 can function in a similar manner as the angled sidewall 14c of FIGS. 8A and 8B that is angled non-perpendicular with the wave propagation direction of the phase cancelling circuit 4. The angled electrical connection line 44 can be angled non-perpendicular with the wave propagation direction of the phase cancelling circuit 4. The angled electrical connection line 44 can enable one or more resonators to be positioned in the acoustic track At.

FIG. 9D is a schematic top plan view of a portion of a multi-layer piezoelectric substrate (MPS) surface acoustic wave (SAW) device that includes an acoustic obstacle 46. FIG. 9E is a cross-sectional side view of FIG. 9D. Unless otherwise noted, the components shown in FIGS. 9D and 9E may be structurally and/or functionally the same as or generally similar to like components disclosed herein. The acoustic obstacle 46 can be a trench in the piezoelectric layer 14. The trench can contribute to reducing and/or eliminating acoustic coupling between the phase cancelling circuit 4 and a resonator in the acoustic track At of the phase cancelling circuit 4. The acoustic obstacle 46 can be angled non-perpendicular with the wave propagation direction of the phase cancelling circuit 4 so as to function in a similar manner as the angled sidewall 14c of FIGS. 8A and 8B that is angled non-perpendicular with the wave propagation direction of the phase cancelling circuit 4.

FIG. 10 is a schematic top plan view of a portion of a multi-layer piezoelectric substrate (MPS) surface acoustic wave (SAW) device that includes a reflector 48. Unless otherwise noted, the components shown in FIG. 10 may be structurally and/or functionally the same as or generally similar to like components disclosed herein. The reflector 48 can prevent or mitigate the acoustic wave from the phase cancelling circuit 4 to propagate to beyond the reflector 48 such that unwanted reflection back to the phase cancelling circuit 4 can be reduced or eliminated.

In some embodiments, any number of reflection suppression structures disclosed herein can be implemented in an MPS-SAW device. In some embodiments, the phase cancelling circuit 4 can be positioned between a pair of reflection suppression structures. For example, an MPS-SAW device can include a first reflection suppression structure that includes the tapered and/or angled sidewall 14c as shown in FIGS. 1B and 8B, the acoustic obstacles 40, the acoustic obstacle 42, the angled electrical connection line 44, the acoustic obstacle 46, or the reflector 48, and a second reflection suppression structure that includes the tapered and/or angled sidewall 14c as shown in FIGS. 1B and 8B, the acoustic obstacles 40, the acoustic obstacle 42, the angled electrical connection line 44, the acoustic obstacle 46, or the reflector 48 that are positioned in the acoustic track of the phase cancelling circuit 4, and the phase cancelling circuit 4 can be positioned between the first and second reflection suppression structures. The acoustic obstacles disclosed herein can be referred to as acoustic obstruction structures.

An acoustic wave device (e.g., a SAW device) including any suitable combination of features disclosed herein can be included in a filter arranged to filter a radio frequency signal in a fifth generation (5G) New Radio (NR) operating band within Frequency Range 1 (FR1). A filter arranged to filter a radio frequency signal in a 5G NR operating band can include one or more packaged MPS-SAW devices disclosed herein. FR1 can be from 410 MHz to 7.125 GHz, for example, as specified in a current 5G NR specification. One or more acoustic wave devices in accordance with any suitable principles and advantages disclosed herein can be included in a filter arranged to filter a radio frequency signal in a 4G LTE operating band and/or in a filter having a passband that includes a 4G LTE operating band and a 5G NR operating band.

FIG. 11 is a schematic diagram of a radio frequency module 175 that includes a surface acoustic wave component 176. The illustrated radio frequency module 175 includes the SAW component 176 and other circuitry 177. The SAW component 176 can include one or more SAW devices with any suitable combination of features of the SAW devices disclosed herein. The SAW component 176 can include a SAW die that includes SAW resonators.

The SAW component 176 shown in FIG. 11 includes a filter 178 and terminals 179A and 179B. The filter 178 includes SAW resonators. One or more of the SAW resonators can be implemented in accordance with any suitable principles and advantages of any surface acoustic wave device disclosed herein. The terminals 179A and 178B can serve, for example, as an input contact and an output contact. The SAW component 176 and the other circuitry 177 are on a common packaging substrate 180 in FIG. 11. The package substrate 180 can be a laminate substrate. The terminals 179A and 179B can be electrically connected to contacts 181A and 181B, respectively, on the packaging substrate 180 by way of electrical connectors 182A and 182B, respectively. The electrical connectors 182A and 182B can be bumps or wire bonds, for example. The other circuitry 177 can include any suitable additional circuitry. For example, the other circuitry can include one or more one or more power amplifiers, one or more radio frequency switches, one or more additional filters, one or more low noise amplifiers, the like, or any suitable combination thereof. The radio frequency module 175 can include one or more packaging structures to, for example, provide protection and/or facilitate easier handling of the radio frequency module 175. Such a packaging structure can include an overmold structure formed over the packaging substrate 180. The overmold structure can encapsulate some or all of the components of the radio frequency module 175.

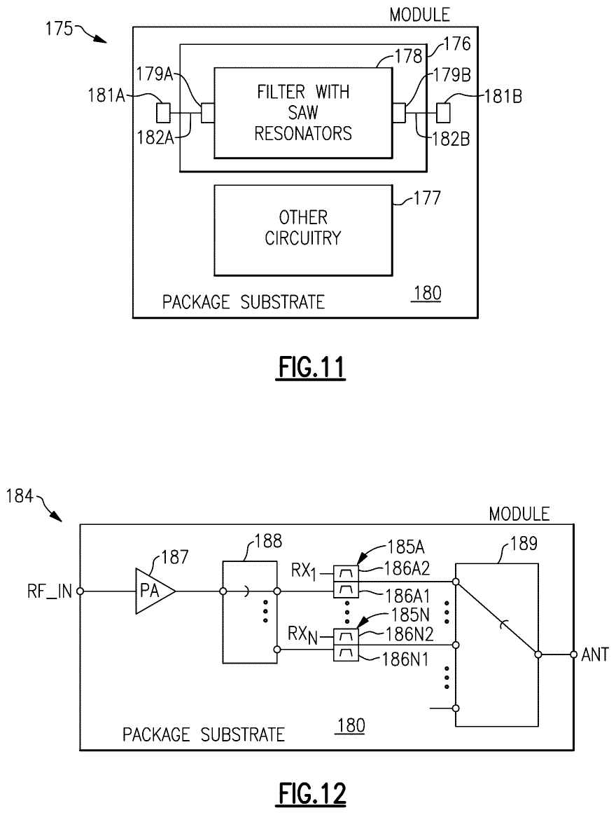

FIG. 12 is a schematic diagram of a radio frequency module 184 that includes a surface acoustic wave resonator according to an embodiment. As illustrated, the radio frequency module 184 includes duplexers 185A to 185N that include respective transmit filters 186A1 to 186N1 and respective receive filters 186A2 to 186N2, a power amplifier 187, a select switch 188, and an antenna switch 189. In some instances, the module 184 can include one or more low noise amplifiers configured to receive a signal from one or more receive filters of the receive filters 186A2 to 186N2. The radio frequency module 184 can include a package that encloses the illustrated elements. The illustrated elements can be disposed on a common packaging substrate 180. The packaging substrate can be a laminate substrate, for example.

The duplexers 185A to 185N can each include two acoustic wave filters coupled to a common node. The two acoustic wave filters can be a transmit filter and a receive filter. As illustrated, the transmit filter and the receive filter can each be band pass filters arranged to filter a radio frequency signal. One or more of the transmit filters 186A1 to 186N1 can include one or more SAW resonators in accordance with any suitable principles and advantages disclosed herein. Similarly, one or more of the receive filters 186A2 to 186N2 can include one or more SAW resonators in accordance with any suitable principles and advantages disclosed herein. Although FIG. 12 illustrates duplexers, any suitable principles and advantages disclosed herein can be implemented in other multiplexers (e.g., quadplexers, hexaplexers, octoplexers, etc.) and/or in switch-plexers and/or to standalone filters.

The power amplifier 187 can amplify a radio frequency signal. The illustrated switch 188 is a multi-throw radio frequency switch. The switch 188 can electrically couple an output of the power amplifier 187 to a selected transmit filter of the transmit filters 186A1 to 186N1. In some instances, the switch 188 can electrically connect the output of the power amplifier 187 to more than one of the transmit filters 186A1 to 186N1. The antenna switch 189 can selectively couple a signal from one or more of the duplexers 185A to 185N to an antenna port ANT. The duplexers 185A to 185N can be associated with different frequency bands and/or different modes of operation (e.g., different power modes, different signaling modes, etc.).

FIG. 13 is a schematic block diagram of a module 190 that includes duplexers 191A to 191N and an antenna switch 192. One or more filters of the duplexers 191A to 191N can include any suitable number of surface acoustic wave resonators in accordance with any suitable principles and advantages discussed herein. Any suitable number of duplexers 191A to 191N can be implemented. The antenna switch 192 can have a number of throws corresponding to the number of duplexers 191A to 191N. The antenna switch 192 can electrically couple a selected duplexer to an antenna port of the module 190.

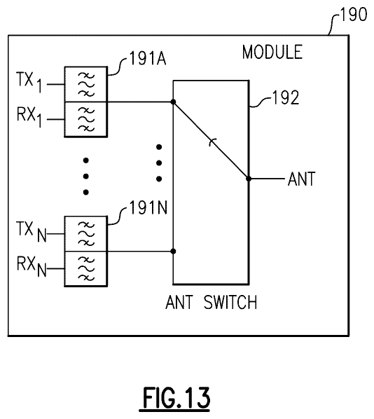

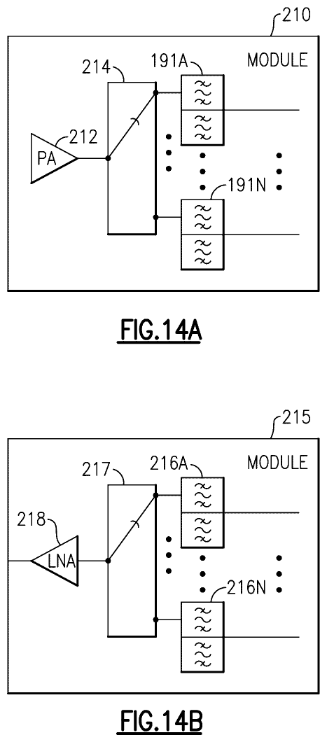

FIG. 14A is a schematic block diagram of a module 210 that includes a power amplifier 212, a radio frequency switch 214, and duplexers 191A to 191N in accordance with one or more embodiments. The power amplifier 212 can amplify a radio frequency signal. The radio frequency switch 214 can be a multi-throw radio frequency switch. The radio frequency switch 214 can electrically couple an output of the power amplifier 212 to a selected transmit filter of the duplexers 191A to 191N. One or more filters of the duplexers 191A to 191N can include any suitable number of surface acoustic wave resonators in accordance with any suitable principles and advantages discussed herein. Any suitable number of duplexers 191A to 191N can be implemented.

FIG. 14B is a schematic block diagram of a module 215 that includes filters 216A to 216N, a radio frequency switch 217, and a low noise amplifier 218 according to an embodiment. One or more filters of the filters 216A to 216N can include any suitable number of acoustic wave resonators in accordance with any suitable principles and advantages disclosed herein. Any suitable number of filters 216A to 216N can be implemented. The illustrated filters 216A to 216N are receive filters. In some embodiments, one or more of the filters 216A to 216N can be included in a multiplexer that also includes a transmit filter. The radio frequency switch 217 can be a multi-throw radio frequency switch. The radio frequency switch 217 can electrically couple an output of a selected filter of filters 216A to 216N to the low noise amplifier 218. In some embodiments, a plurality of low noise amplifiers can be implemented. The module 215 can include diversity receive features in certain applications.

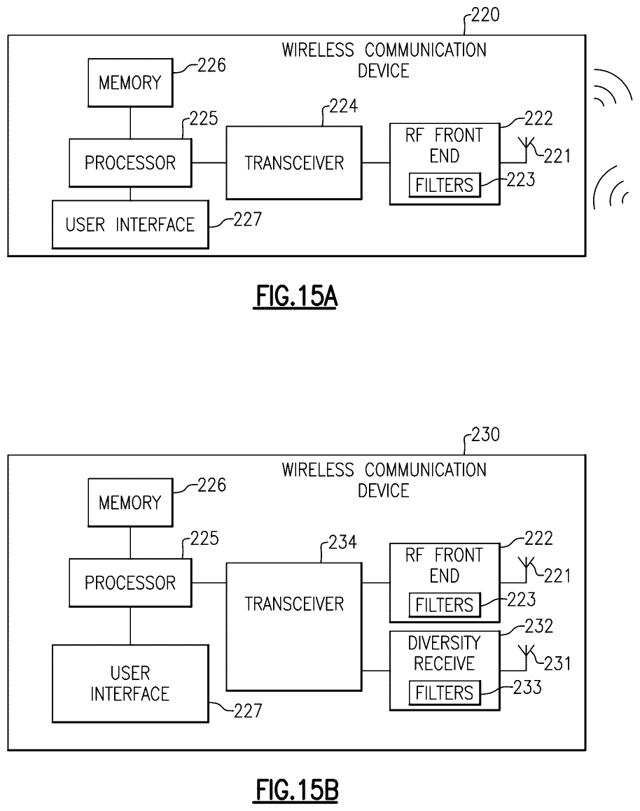

FIG. 15A is a schematic diagram of a wireless communication device 220 that includes filters 223 in a radio frequency front end 222 according to an embodiment. The filters 223 can include one or more SAW resonators in accordance with any suitable principles and advantages discussed herein. The wireless communication device 220 can be any suitable wireless communication device. For instance, a wireless communication device 220 can be a mobile phone, such as a smart phone. As illustrated, the wireless communication device 220 includes an antenna 221, an RF front end 222, a transceiver 224, a processor 225, a memory 226, and a user interface 227. The antenna 221 can transmit/receive RF signals provided by the RF front end 222. Such RF signals can include carrier aggregation signals. Although not illustrated, the wireless communication device 220 can include a microphone and a speaker in certain applications.

The RF front end 222 can include one or more power amplifiers, one or more low noise amplifiers, one or more RF switches, one or more receive filters, one or more transmit filters, one or more duplex filters, one or more multiplexers, one or more frequency multiplexing circuits, the like, or any suitable combination thereof. The RF front end 222 can transmit and receive RF signals associated with any suitable communication standards. The filters 223 can include SAW resonators of a SAW component that includes any suitable combination of features discussed with reference to any embodiments discussed above.

The transceiver 224 can provide RF signals to the RF front end 222 for amplification and/or other processing. The transceiver 224 can also process an RF signal provided by a low noise amplifier of the RF front end 222. The transceiver 224 is in communication with the processor 225. The processor 225 can be a baseband processor. The processor 225 can provide any suitable base band processing functions for the wireless communication device 220. The memory 226 can be accessed by the processor 225. The memory 226 can store any suitable data for the wireless communication device 220. The user interface 227 can be any suitable user interface, such as a display with touch screen capabilities.

FIG. 15B is a schematic diagram of a wireless communication device 230 that includes filters 223 in a radio frequency front end 222 and a second filter 233 in a diversity receive module 232. The wireless communication device 230 is like the wireless communication device 220 of FIG. 15A, except that the wireless communication device 230 also includes diversity receive features. As illustrated in FIG. 15B, the wireless communication device 230 includes a diversity antenna 231, a diversity module 232 configured to process signals received by the diversity antenna 231 and including filters 233, and a transceiver 234 in communication with both the radio frequency front end 222 and the diversity receive module 232. The filters 233 can include one or more SAW resonators that include any suitable combination of features discussed with reference to any embodiments discussed above.

Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes some example embodiments, the teachings described herein can be applied to a variety of structures. Any of the principles and advantages discussed herein can be implemented in association with RF circuits configured to process signals in a frequency range from about 30 kHz to 300 GHz, such as in a frequency range from about 450 MHz to 8.5 GHz. Acoustic wave resonators and/or filters disclosed herein can filter RF signals at frequencies up to and including millimeter wave frequencies.

Aspects of this disclosure can be implemented in various electronic devices. Examples of the electronic devices can include, but are not limited to, consumer electronic products, parts of the consumer electronic products such as packaged radio frequency modules and/or packaged filter components, uplink wireless communication devices, wireless communication infrastructure, electronic test equipment, etc. Examples of the electronic devices can include, but are not limited to, a mobile phone such as a smart phone, a wearable computing device such as a smart watch or an car piece, a telephone, a television, a computer monitor, a computer, a modem, a hand-held computer, a laptop computer, a tablet computer, a microwave, a refrigerator, a vehicular electronics system such as an automotive electronics system, a stereo system, a digital music player, a radio, a camera such as a digital camera, a portable memory chip, a washer, a dryer, a washer/dryer, a copier, a facsimile machine, a scanner, a multi-functional peripheral device, a wrist watch, a clock, etc. Further, the electronic devices can include unfinished products.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. As used herein, the term “approximately” intends that the modified characteristic need not be absolute, but is close enough so as to achieve the advantages of the characteristic. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

What is claimed is:

1. A multi-layer piezoelectric substrate surface acoustic wave device comprising:
a multi-layer piezoelectric substrate including a support substrate and a piezoelectric layer, the piezoelectric layer having a first side facing the support substrate, a second side opposite the first side, and a sidewall extending between the first side and the second side and defining a periphery of the piezoelectric layer, the sidewall tapered such that the first side is wider than the second side;
a filter circuit including a plurality of resonators in electrical communication with the piezoelectric layer; and
a phase cancelling circuit integrated with the filter circuit, an acoustic track of the phase cancelling circuit being offset from the plurality of resonators.

2. The acoustic wave device of claim 1 wherein an angle between the second side and the sidewall is in a range between 15° and 80°.

3. The acoustic wave device of claim 1 wherein the multi-layer piezoelectric substrate further includes a silicon oxide layer between the support substrate and the piezoelectric layer.

4. The acoustic wave device of claim 1 wherein the filter circuit includes a transmit filter connected to an antenna and a receive filter connected to the antenna, the phase cancelling circuit is electrically connected between a transmit port of the transmit filter and the antenna and between a receive port of the receive filter and the antenna.

5. The acoustic wave device of claim 1 wherein the phase cancelling circuit includes a plurality of longitudinally coupled interdigital transducer electrodes.

6. The acoustic wave device of claim 1 further comprising an acoustic wave obstacle in the acoustic track.

7. The acoustic wave device of claim 6 wherein the acoustic wave obstacle includes a reflector.

8. The acoustic wave device of claim 1 further comprising a second filter circuit including a second plurality of resonators in electrical communication with the piezoelectric layer, and a second phase cancelling circuit integrated with the second filter circuit.

9. The acoustic wave device of claim 8 wherein a second acoustic track of the second phase cancelling circuit being offset from the second plurality of resonators.

10. The acoustic wave device of claim 1 wherein the acoustic track of the phase cancelling circuit being is free from the plurality of resonators.

11. A method of manufacturing a multi-layer piezoelectric substrate surface acoustic wave device, the method comprising:
providing a multi-layer piezoelectric substrate including a support substrate and a piezoelectric layer, the piezoelectric layer having a first side facing the support substrate, a second side opposite the first side, and a sidewall extending between the first side and the second side and defining a periphery of the piezoelectric layer, the sidewall tapered such that the first side is wider than the second side;
forming a filter circuit including a plurality of resonators in electrical communication with the piezoelectric layer; and
providing a phase cancelling circuit integrated with the filter circuit, an acoustic track of the phase cancelling circuit being offset from the plurality of resonators.

12. The method of claim 11 wherein an angle between the second side and the sidewall is in a range between 15° and 80°.

13. The method of claim 11 wherein the multi-layer piezoelectric substrate further includes a silicon oxide layer between the support substrate and the piezoelectric layer.

14. The method of claim 11 wherein the filter circuit includes a transmit filter connected to an antenna and a receive filter connected to the antenna, the phase cancelling circuit is electrically connected between a transmit port of the transmit filter and the antenna and between a receive port of the receive filter and the antenna.

15. The method of claim 11 wherein the phase cancelling circuit includes a plurality of longitudinally coupled interdigital transducer electrodes.

16. The method of claim 11 further comprising an acoustic wave obstacle in the acoustic track.

17. The method of claim 16 wherein the acoustic wave obstacle includes a reflector.

18. The method of claim 11 further comprising a second filter circuit including a second plurality of resonators in electrical communication with the piezoelectric layer, and a second phase cancelling circuit integrated with the second filter circuit, wherein a second acoustic track of the second phase cancelling circuit being offset from the second plurality of resonators.

19. The method of claim 11 wherein the acoustic track of the phase cancelling circuit being is free from the plurality of resonators.

20. A multi-layer piezoelectric substrate surface acoustic wave device comprising:
a multi-layer piezoelectric substrate including a support substrate and a piezoelectric layer, the piezoelectric layer having a first side facing the support substrate, a second side opposite the first side, and a sidewall extending between the first side and the second side and defining a periphery of the piezoelectric layer, the sidewall tapered such that the first side is wider than the second side;
a filter circuit including a plurality of resonators in electrical communication with the piezoelectric layer; and
a phase cancelling circuit integrated with the filter circuit, none of the plurality of resonators positioned in an acoustic track of the phase cancelling circuit.
